(19) United States
(12) Patent Application Publication
(10) Pub. No.: US 2007/0066023 A1
(43) Pub. Date: Mar. 22, 2007

(54) METHOD TO FORM A DEVICE ON A SOI SUBSTRATE

(76) Inventors: Randhir Thakur, San Jose, CA (US); Michael Splinter, Los Altos Hills, CA (US)

Correspondence Address: PATTERSON & SHERIDAN, LLP, 3040 POST OAK BOULEVARD, SUITE 1500, HOUSTON, TX, 77056, US

(21) Appl. No.: 11/532,710

(22) Filed: Sep. 18, 2006

Related U.S. Application Data
(60) Provisional application No. 60/718,806, filed on Sep. 20, 2005.

(51) Int. Cl. H01L 21/336

(52) U.S. Cl. 438/300; 438/294; 438/301

(57) ABSTRACT

A method and apparatus for depositing a planar silicon containing layer, depositing an oxide layer, patterning the oxide layer to expose regions of the silicon containing layer above remaining regions of the oxide layer, selectively depositing a silicon and germanium containing layer on the regions of the silicon containing layer, and then etching the remaining regions of the oxide layer are provided. A method and apparatus for forming an oxide box on a SOI substrate, depositing a planar silicon containing layer comprising depositing a germanium layer, depositing a silicon germanium layer, and depositing a silicon layer, depositing an oxide layer, patterning the oxide layer while overetching the planar silicon containing layer to expose regions of the planar silicon containing layer within remaining regions of the oxide layer, depositing a silicon and germanium containing layer within the regions of the planar silicon containing layer, and then etching the remaining regions of the oxide layer are also provided.

### CROSS-REFERENCE TO RELATED APPLICATIONS

This application claims benefit of U.S. provisional patent application Ser. No. 60/718,806, filed Sep. 20, 2005, which is herein incorporated by reference.

### FIELD OF THE INVENTION

Embodiments of the invention generally relate to the field of semiconductor manufacturing processes and devices, more particular, to methods of depositing silicon-containing materials and films to form semiconductor devices.

### DESCRIPTION OF THE RELATED ART

PD (partially depleted)-SOI (silicon-on-insulator)-CMOS (complementary metal oxide semiconductor) technology has significant speed, power, and radiation immunity advantages over other semiconductor manufacturing technology. However, it has been difficult to manage the floating body effect (FBE) of SOI devices. One problem associated with PD-SOI-CMOS devices involves an unstable body potential over a range of frequencies.

In bulk metal oxide semiconductor field effect transistors with n-type channels (NMOSFET) devices, for example, the body often is tied to a fixed potential or to the source of the device. However, the body potential in NMOSFET-SOI is floating and remains unstable due to the complex dynamics of hole generation at the drain edge, and due to carrier recombination and diffusion. Several undesirable characteristics results from FBE, such as “Kink Effect” (current enhancement) in Id-Vg characteristics of the device, enhanced leakage due to parasitic (npn) bipolar (BJT) current, and enhanced 1/f noise. These effects restrict the ability to design complex circuits and the range of applications for SOI technology. Circuit-related issues attributable to FBE include threshold instability, hysteretic behavior in signal input/output, frequency-dependent pulse delays, and signal pulse width modulation.

In logic design, FBE can lead to data loss, dynamic circuit failure and timing delays. Additionally, FBE can limit analog circuit applications due to transistor mismatch and enhanced AC/DC noise.

Selective epitaxy is a useful deposition process for forming elevated source/drain and source/drain extension features when using silicon-germanium materials for complementary metal-oxide semiconductor (CMOS) devices. Etching silicon to make a recessed source/drain feature and subsequently filling the etched surface with a selectively grown silicon-germanium epilayer forms source/drain extension features. Selective epitaxy processes permit near complete dopant activation with in-situ doping, therefore removing or at least reducing the need of a drying process after annealing. Selective epitaxy processes and silicon etching processes may accurately define junction depth. Unfortunately, an ultra shallow source/drain junction inevitably results in increased series resistance because of junction consumption. Junction consumption during silicide formation further increases the series resistance. In order to compensate for junction consumption, an elevated source/drain may be epitaxially and selectively grown on the junction.

Generally, a selective epitaxy process involves two competing chemical reactions, deposition reactions, and etching reactions. The deposition and etching reactions occur simultaneously with relatively different reaction rates on single crystalline silicon surfaces and on dielectric surfaces. A selective process window results in the deposition of a material on exposed silicon surfaces, and not on exposed dielectric surfaces, by adjusting the concentration of an etchant gas (e.g., HCl). Selective epitaxial deposition provides growth of epilayers on silicon moats with no growth on dielectric areas. Selective epitaxy may be used to deposit silicon or silicon-germanium materials in semiconductor devices, such as within elevated source/drains, source/drain extensions, contact plugs, and base layer deposition of bipolar devices.

Although epitaxial deposition of silicon-germanium materials is suitable for small dimensions, the process does not readily form doped silicon-germanium, because the dopants react with hydrogen chloride. Manufacturing heavily boron doped (e.g., higher than 5×10¹⁹ cm⁻³) selective silicon-germanium epitaxy material is a complicated task because boron doping makes the process window for selective deposition narrow. Generally, when a deposition gas contains an increase of the boron concentration (e.g., B₂H₆), an increase of the hydrogen chloride concentration is necessary to achieve selectivity due to the increase growth rate of deposited material on dielectric areas. The increased hydrogen chloride concentration reduces boron incorporation into the epilayers.

Currently, there are two popular applications for a selective silicon-based epitaxy process in junction formation of silicon-containing MOSFET (metal oxide semiconductor field effect transistor) devices. One application is to deposit elevated source/drain (S/D) films by a selective epitaxy process. Typically, the epitaxial layer is undoped silicon. Often, there is not enough silicon to create a recessed structure. Another application is to fill recessed junction areas with epitaxial silicon-containing material, usually containing germanium, carbon, or another dopant.

A silicon-germanium material is used for PMOS application for several reasons. A silicon-germanium material incorporates more boron than silicon alone, and the resulting junction has a lower resistivity. Also, a silicon-germanium/silicide layer interface at the substrate surface has a lower Schottky barrier than a silicon/silicide interface. Further, a silicon-germanium layer grown epitaxially on the top of a silicon layer may provide compressive stress inside the film because the lattice constant of silicon-germanium is larger than that of silicon. The compressive stress is transferred in the lateral dimension to create compressive strain in the PMOS channel and to increase mobility of the holes.

For NMOS applications, a silicon-carbon material may be used in the recessed areas to create tensile stress in the channel because the lattice constant of silicon-carbon is smaller than that of silicon. The tensile stress is transferred into the channel and increases the electron mobility.

While past techniques have used an epitaxial deposition process to manufacture devices with silicon germanium compounds, the resulting crystalline structure can not be selected to optimize intermolecular strain properties. Therefore, there is a need to have a process for improving the performance of silicon on insulator devices by improving device strain properties. Furthermore, the process should be versatile to form silicon-containing materials with varied silicon concentration.

### SUMMARY OF THE INVENTION

The present invention generally provides a method and apparatus for depositing a planar silicon containing layer, depositing an oxide layer, patterning the oxide layer to expose regions of the silicon containing layer above remaining regions of the oxide layer, selectively depositing a silicon and germanium containing layer on the regions of the silicon containing layer, and then etching the remaining regions of the oxide layer. Additionally, the present invention generally provides a method and apparatus for forming an oxide box on a SOI substrate, depositing a planar silicon containing layer comprising depositing a germanium layer, depositing a silicon germanium layer, and depositing a silicon layer, depositing an oxide layer, patterning the oxide layer while overetching the planar silicon containing layer to expose regions of the planar silicon containing layer within remaining regions of the oxide layer, depositing a silicon and germanium containing layer within the regions of the planar silicon containing layer, and then etching the remaining regions of the oxide layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1D illustrate cross-sectional views of a substrate structure at different stages of integrated circuit fabrication.

FIG. 2 is a cross sectional view of a substrate structure.

FIG. 3 is a flow diagram of a process to deposit a structure.

### DETAILED DESCRIPTION

The present invention provides a process for depositing silicon containing compounds during the manufacture of various device structures. In some embodiments, silicon germanium compounds are selected to improve the structure strain properties. Overetching is used in some embodiments to form recesses in part of the structure and encourage crystallinity properties and strain profiles that are enhanced for the resulting structures.

Silicon containing materials, compounds, films, or layers should be construed to include a composition containing at least silicon and may contain germanium, carbon, boron, arsenic and/or phosphorous. Other elements, such as metals, halogens, or hydrogen may be incorporated within a silicon-containing material, film, or layer, usually as impurities. Silicon containing materials may be represented by abbreviation, such as Si for silicon, SiGe for silicon-germanium, SiC for silicon carbon and SiGeC for silicon-germanium carbon. The abbreviations do not represent chemical equations with stoichiometric relationships, nor represent any particular reduction/oxidation state of the constituents in the silicon containing materials.

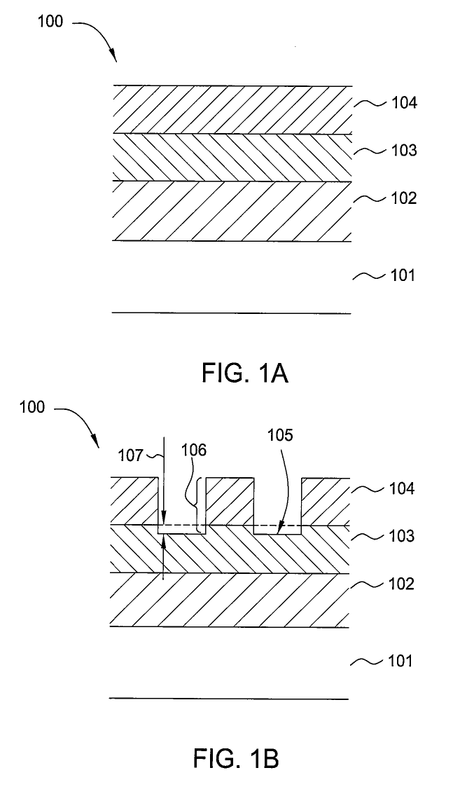

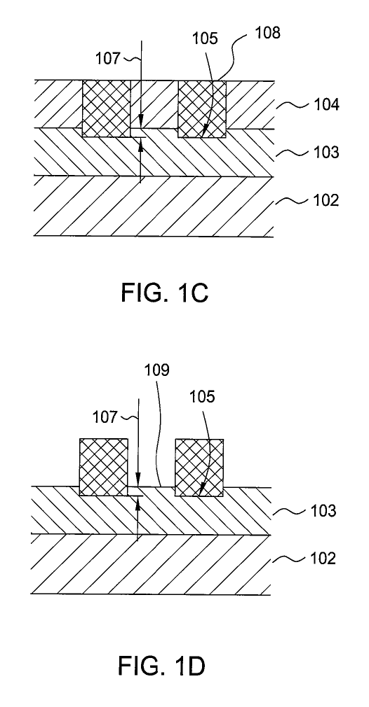

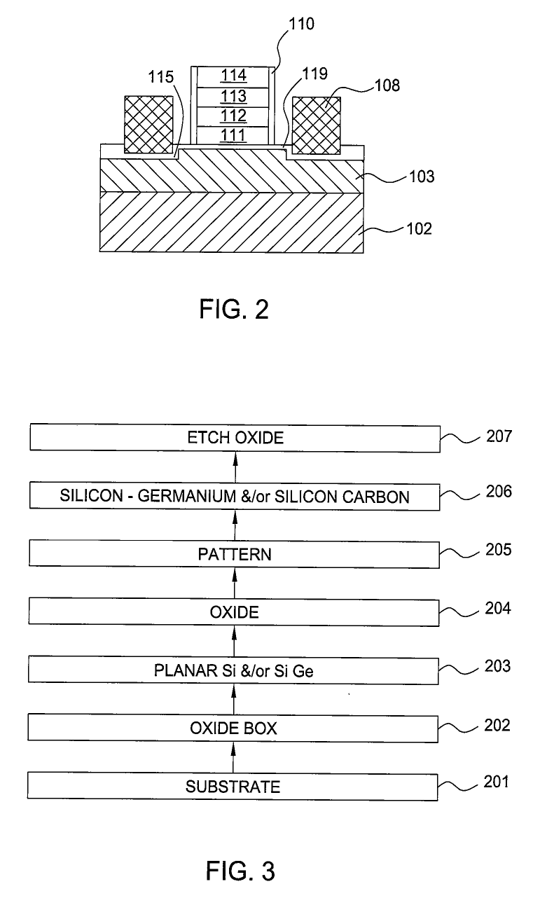

FIGS. 1A-1D illustrate a cross-sectional view of a structure 100 of a semiconductor device comprising both silicon germanium and overetching to enhance performance. FIG. 2 is a completed SOI structure and FIG. 3 is a flow diagram of a process to deposit the completed SOI structure. Step 201 of FIG. 3 is providing a silicon on insulator (SOI) substrate 101 shown in FIGS. 1A and 1B. SOI substrates may be formed by any common method when oxygen ions are implanted into Si substrate and form a buried oxide layer such as NANOCLEAVE™, SMARTCUT™, or SIMOx™. NANOCLEAVE™ is a trademark of Silicon Genesis Corporation of San Jose, Calif. SMARTCUT™ is a trademark of S.O.I.TEC, S.A., of Grenoble, France. SIMOx™ is a trademark of Ibis Technology Corporation of Danvers, Mass. and is an abbreviation for separation by implantation of oxygen.

Step 202 of FIG. 3 indicates that a buried oxide (BOX) layer 102 of FIGS. 1A-1D is formed on a surface of the SOI substrate 101 as part of the SOI manufacturing process. The step 202 may also include forming silicon oxide during transport of the substrate or other pre-deposition process steps.

Step 203 deposits a planar layer 103 across the surface of BOX layer 102. Planar layer 103 may be pure silicon, a silicon carbon compound, or a silicon germanium compound. When the planar layer 103 is silicon germanium, the silicon germanium compound can have a strained crystalline structure as known in the art. Alternatively, the planar layer 103 may have a concentration gradient such that pure germanium is deposited, then germanium silicon, then pure silicon is deposited to form the upper portion of the planar layer 103. The concentration gradient may have a bottom portion with a germanium concentration of 0 to 100 percent germanium, a transition portion, and an upper portion with a silicon concentration of up to 100 percent. A small percentage of carbon, ie., up to 50 percent, may be dispersed throughout the planar layer 103. Alternatively, only the upper or lower portion of planar layer 103 may contain carbon. The precursors that may be selected for the deposition of planar layer 103 include trisilane, disilane, silane, dichlorosilane, and other chlorine based hydrides.

Germanium and germanium silicon materials, although often overlooked in modern semiconductor manufacturing because germanium has a high rate of diffusion, are acceptable for SOI devices because germanium diffusion into the oxide box has no influence over the resulting transistor performance.

FIG. 1A further illustrates a stack of layers formed on top of the silicon on insulator substrate 101. Step 204 of FIG. 3 includes growth of an oxide layer 104 on top of the planar layer 103. The oxide layer 104 is a silicon oxide layer that is grown or deposited with a thickness of at least 50 Å. The oxide layer 104 may be deposited by low pressure chemical vapor deposition (LPCVD), pure vacuum chemical vapor deposition (PVCVD), or other growth mechanisms. Generally, the oxide layer 104 may be deposited by all other oxide layer deposition processes such as atomic layer deposition (ALD) or chemical vapor deposition (CVD).

Step 205 of FIG. 3 includes patterning the oxide layer 104. FIG. 1B illustrates a patterned oxide layer 104 which has been patterned by an etching method. Etching can be performed by a number of processes such as systems that are configured for use in the ENDURA™ and CENTURA™ integrated tools that are commercially available from Applied Materials of Santa Clara, Calif. Oxide layer 104 is preferably overetched. That is, the base of the via formed by the etching process is below the surface of the planar layer 103. The etching distance 106 into the oxide layer 104 may be significantly greater than the thickness of the oxide layer 104. The recess 105 that is formed has a depth 107 that is the difference between the etching distance 106 and the thickness of oxide layer 104. The recess depth 107 is about 0 to about 150 Å.

FIG. 3 further shows a silicon germanium or silicon carbon deposition step 206. The cross sectional view of a structure after the silicon germanium or silicon carbon deposition step 206 is illustrated by FIG. 1C. The silicon germanium or silicon carbon layer 108 fills the vias and the recess 105 formed by overetching in step 205. The deposition step 206 may be selective or blanket deposition or the deposition may use a mask. The silicon germanium or silicon carbon layer 108 is selected to provide a boundary region with optimum crystalline structure that effectively interacts with the planar layer 103. The strain profile is optimized by tuning the silicon and germanium and carbon content of both the silicon germanium or silicon carbon layer 108 and planar layer 103. The silicon germanium or silicon carbon layer 108 may also be silicon germanium carbon or other material with a similar crystalline structure that benefits from similar strain profile tailoring. A planarization step may follow the deposition step 206.

FIG. 3 further shows an etch oxide step 207. FIG. 1D illustrates the cross sectional view of an SOI structure after etch oxide step 207 is performed. Etch oxide step 207 removes the oxide surrounding the silicon germanium or silicon carbon 108. Etch oxide step 207 exposes the surface of the planar layer 103, while not influencing the recess 105 in the planar layer 103. The surface 109 of the planar layer 103 may be pure silicon. The pure silicon along the surface 109 may be utilized in further processing steps and is most desirable for selective deposition processes. Also, the way the silicon germanium or silicon carbon 108 extends into the planar layer 103 provides a strain profile and crystalline structure that helps to minimize the floating body effect.

FIG. 2 illustrates a transistor having a gate structure formed according to one embodiment of the invention. The plurality of field isolation regions containing silicon germanium or silicon carbon 108 isolate a well in the planar layer 103 of one type conductivity (e.g., p-type) from adjacent wells of other types of conductivity (e.g., n-type). A gate dielectric layer 111 is formed on the box oxide 102 and on planar layer 103. Typically, gate dielectric layer 111 may be formed by depositing or growing a layer of a material such as silicon oxide (SiOₙ) and/or silicon oxynitride, having a dielectric constant less than about 5.0. Recent advances in gate dielectric technology indicate that higher dielectric constant materials (K>10) are desirable for forming gate dielectric layer 111. Examples of suitable materials to be employed therefore include, but are not limited to, metal oxides (Al₂O₃, ZrO₂, HfO₂, TiO₂, Y₂O₃, and La₂O₃), ferroelectrics (lead zirconate titanate (PZT) and barium strontium titanate (BST)), amorphous metal silicates (HfSiₓO_{y} and ZrSiₓO_{y}), amorphous silicate oxides (HfO₂, and ZrO₂), and paralectrics (Ba,Sr₁₋ₓTiO₃ and PbZrₓTi₁₋ₓO₃). High k layers containing these materials may be formed by various deposition processes.

Further, an electrically conductive gate electrode layer 112 is blanket deposited over gate dielectric layer 111. Generally, the gate electrode layer 112 may comprise a material such as doped polysilicon, undoped polysilicon, silicon carbide, or silicon-germanium compounds. However, contemplated embodiments may encompass a gate electrode layer 112 containing a metal, metal alloy, metal oxide, single crystalline silicon, amorphous silicon, silicide, or other material well known in the art for forming gate electrodes.

A hard-mask layer 113, such as a nitride layer, is deposited via a CVD process over electrically conductive layer 112. A photolithography process is then carried out including the steps of masking, exposing, and developing a photoresist layer to form a photoresist mask (not shown). The pattern of the photoresist mask is transferred to the hard-mask layer by etching the hard-mask layer to the top of the gate electrode layer 112, using the photoresist mask to align the etch, thus producing a hard-mask 113 over the gate electrode layer 112. An additional layer 114 may be deposited over hard-mask layer 113.

The structure is further modified by removing the photoresist mask and etching the gate electrode layer 112 down to the top of the dielectric layer 111, using the hard-mask to align the etch, thus creating a conductive structure including the remaining material of gate electrode layer 112 underneath the hard-mask. This structure results from etching the gate electrode layer 112, but not the hard-mask or gate dielectric layer 111. Continuing the processing sequence, gate dielectric layer 111 is etched to the top of the planar layer 103. The gate electrode 112 and the gate dielectric 111 together define a composite structure, sometimes known as a gate stack, or gate, of an integrated device, such as a transistor.

In further processing of the gate stack, shallow source/drain extensions 119 are formed by utilizing an implant process. The gate electrode 112 protects the substrate region beneath the gate dielectric 111 from being implanted with ions. A rapid thermal process (RTP) anneal may then be performed to drive the tips 115 partially underneath the gate dielectric 111.

Next, a conformal thin oxide layer 110 is deposited over the entire substrate surface. This oxide layer is used to protect the silicon surface from the spacer layer (not shown), which is typically a silicon nitride layer. The conformal thin oxide layer is typically deposited with TEOS source gas in a low pressure chemical vapor deposition chamber at high temperature (>600° C.). The thin oxide layer relaxes the stress between the silicon substrate and the nitride spacer and it also protects the gate corners from the silicon nitride spacer by providing another layer of material. If low k and non-silicon-nitride material is used as sidewall spacer, this conformal thin oxide layer 110 can possibly be eliminated or replaced by another low k material.

For advanced device manufacturing, if the dielectric constant of the spacer layer (not shown) or oxide layer 110 is too high, the resulting structure often results in excessive signal crosstalk. In addition, thermal CVD processes used to deposit silicon nitride often require high deposition temperature. The high deposition temperature often results in high thermal cycle and an altered dopant profile of tip 109. Therefore, it is desirable to have a spacer layer deposition process with lower deposition temperature.

While the foregoing is directed to embodiments of the present invention, other and further embodiments of the invention may be devised without departing from the basic scope thereof, and the scope thereof is determined by the claims that follow.

What is claimed is:

1. A method of forming a SOI structure, comprising:
depositing a planar silicon containing layer;
depositing an oxide layer;
patterning the oxide layer to expose regions of the silicon containing layer above remaining regions of the oxide layer;
selectively depositing a silicon and germanium containing layer on the regions of the silicon containing layer; and then
etching the remaining regions of the oxide layer.

2. The method of claim 1, wherein the depositing the planar silicon containing layer comprises:
depositing a germanium layer;
depositing a silicon germanium layer; and then
depositing a silicon layer.

3. The method of claim 2, where in the germanium layer contains about 1 to about 100 percent germanium.

4. The method of claim 2, wherein the silicon layer contains about 1 to about 100 percent silicon.

5. The method of claim 1, wherein the silicon and germanium containing layer contains less than about 50 percent carbon.

6. The method of claim 1, wherein the silicon and germanium containing layer contains less than about 2 percent carbon.

7. The method of claim 1, wherein the silicon and germanium containing layer contains about 1 to about 100 percent germanium.

8. The method of claim 1, wherein the silicon and germanium containing layer contains about 50 to about 100 percent germanium.

9. The method of claim 1, wherein the patterning further comprises overetching into the planar silicon containing layer.

10. The method of claim 1, wherein the patterning forms a recess in the planar silicon containing layer.

11. The method of claim 10, wherein the recess has a thickness of about 150 Å or less.

12. A method of forming a SOI structure, comprising:
forming an oxide box on a SOI substrate;
depositing a planar silicon containing layer comprising:
depositing a germanium layer;
depositing a silicon germanium layer; and
depositing a silicon layer;
depositing an oxide layer;
patterning the oxide layer while overetching the planar silicon containing layer to expose regions of the planar silicon containing layer within remaining regions of the oxide layer;
depositing a silicon and germanium containing layer within the regions of the planar silicon containing layer; and then
etching the remaining regions of the oxide layer.

13. The method of claim 12, wherein the germanium layer contains about 1 to about 100 percent germanium.

14. The method of claim 12, wherein the silicon layer contains about 1 to about 100 percent silicon.

15. The method of claim 12, wherein the silicon and germanium containing layer contains less than about 50 percent carbon.

16. The method of claim 12, wherein the silicon and germanium containing layer contains less than about 2 percent carbon.

17. The method of claim 12, wherein the silicon and germanium containing layer contains about 1 to about 100 percent germanium.

18. The method of claim 12, wherein the silicon and germanium containing layer contains about 50 to about 100 percent germanium.

19. The method of claim 12, wherein the patterning further comprises overetching into the planar silicon containing layer.

20. The method of claim 12, wherein the patterning forms a recess in the planar silicon containing layer.

21. The method of claim 20, wherein the recess has a thickness of about 150 Å or less.
